(19) United States
(12) Patent Application Publication
(10) Pub. No.: US 2008/0168825 A1
(43) Pub. Date: Jul. 17, 2008

(54) SURFACE ACOUSTIC WAVE GAS SENSOR WITH SENSITIVE GETTER LAYER AND PROCESS FOR ITS MANUFACTURE

(75) Inventor: Marco AMIOTTI, Cornaredo (IT)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: SAES GETTERS S.P.A, Lianate (IT)

(21) Appl. No.: 11/737,259

(22) Filed: Apr. 19, 2007

Related U.S. Application Data
(63) Continuation of application No. PCT/IT2005/000605, filed on Oct. 17, 2005.

(30) Foreign Application Priority Data
Oct. 24, 2004 (IT) MI2004A 002017

(51) Int. Cl. G01N 29/036; H01L 41/22

(52) U.S. Cl. 73/24.06; 29/25.35

(57) ABSTRACT

A surface acoustic wave gas sensor, in particular a vacuum or hydrogen sensor, includes a piezoelectric substrate (1) on which at least one layer of a gas-sensitive material (6) is arranged between two inter-digital transducers (2, 3). The gas-sensitive material includes a getter material, such that the molecules sorbed by this getter material can vary the frequency of a signal transmitted between the two transducers (2, 3). A process for manufacturing this sensor is also provided using a mask to deposit the gas-sensitive material between the transducers, preferably by sputtering.

### CROSS-REFERENCE TO RELATED APPLICATIONS

This application is a Section 371 of International Application No. PCT/IT2005/000605, filed Oct. 17, 2005, which was published in the English language on Apr. 27, 2006 under International Publication No. WO/2006/043299, the disclosure of which is incorporated herein by reference.

### BACKGROUND OF THE INVENTION

The present invention relates to a gas sensor embodying the surface acoustic wave or SAW technology, in particular a vacuum or hydrogen sensor. The present invention also relates to a process for manufacturing this sensor.

Known gas sensors comprise a SAW device wherein a layer of a material sensitive to a determined gas is arranged on the piezoelectric substrate of the SAW device between its inter-digital transducers.

The publication Y. J. Lee et al., “Development of a SAW gas sensor for monitoring SO₂ gas”, Sensors and Actuators A 64:173-178 (1998) discloses a sensitive layer of cadmium sulfide for measuring concentrations of SO₂.

U.S. Pat. No. 5,583,282 discloses a sensor comprising a piezoelectric substrate on which at least one layer of a gas-sensitive material is arranged between two inter-digital transducers, the gas-sensitive material comprising a getter material.

U.S. Pat. No. 5,592,215 discloses a sensitive layer of gold, silver or copper for measuring concentrations of mercury.

U.S. Patent Application Publication 2004/0107765 discloses a sensitive layer of cellulose nitrate for measuring concentrations of acetone, benzene, dichloroethane, ethanol, or toluene.

However, the sensors cannot measure concentrations of simple molecules, or even measure the vacuum level in an evacuated environment, due to the relatively low sensitivity of their sensitive layer.

### BRIEF SUMMARY OF THE INVENTION

It is therefore an object of the present invention to provide a SAW sensor free from the disadvantages. The object is achieved with a sensor comprising a piezoelectric substrate on which is present at least one first layer of a gas-sensitive material comprising a getter material arranged between two inter-digital transducers, characterized by further comprising, over the first layer, a second layer of a material permeable to one or more determined gases, being also arranged between the two inter-digital transducers, so that the molecules sorbed by the getter material can vary the frequency of a signal transmitted between the two transducers.

The object is further achieved by a process for manufacturing gas sensors, comprising the following operating steps:

applying a plurality of pairs of inter-digital transducers onto a wafer of a piezoelectric substrate;

arranging onto the wafer a mask provided with calibrated openings, so that these openings are located between a pair of inter-digital transducers;

depositing onto the wafer through the mask a layer of a gas-sensitive material comprising a getter material;

arranging onto the wafer a mask provided with calibrated openings, so that these openings are located between a pair of inter-digital transducers; and

depositing onto the wafer through the mask a layer of a material permeable to one or more determined gases.

Due to the getter material included in the gas-sensitive layer, the sensor according to the present invention can be employed as a vacuum sensor or as a sensor for simple molecules, for example hydrogen, if the sensitive layer is covered by a particular layer of a material permeable to these molecules. In particular, the sensor can be arranged in an evacuated system already provided with a getter, so as to detect when the latter must be regenerated.

A resistive device can be arranged between the piezoelectric substrate and the gas-sensitive layer for activating and/or regenerating the getter material at a high temperature without damaging the transducers with the heat.

The sensitive layer is preferably made of a thin getter film applied by means of Physical Vapor Deposition or “PVD”, commonly also known as “sputtering,” so as to simplify the sensor manufacturing and keep its sensitivity as constant as possible, thus improving its measurement precision.

For further improving the measurement precision of the sensor, a second pair of inter-digital transducers can be arranged on the piezoelectric substrate with the sensitive layer arranged only between the first pair of transducers.

For manufacturing the sensor, masks provided with calibrated openings can be employed for depositing layers having precise dimensions onto a wafer already provided with a plurality of pairs of transducers, so as to reduce the manufacturing times and costs and to reproducibly maintain a high sensor quality.

This technique is known, for example, from European published patent application EP 0 936 734 A1, which discloses a process for manufacturing a SAW device comprising the steps of sputtering tantalum-aluminum layers and using masks to obtain the sensor pattern.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a plan view of a sensor arrangement according to the application;

FIG. 2 is a partial cross-sectional view of a first embodiment of the sensor;

FIG. 3 is a partial cross-sectional view of a second embodiment of the sensor;

FIG. 4 is a plan view of a third embodiment of the sensor; and

FIG. 5 is a plan view of a fourth embodiment of the sensor.

### DETAILED DESCRIPTION OF THE INVENTION

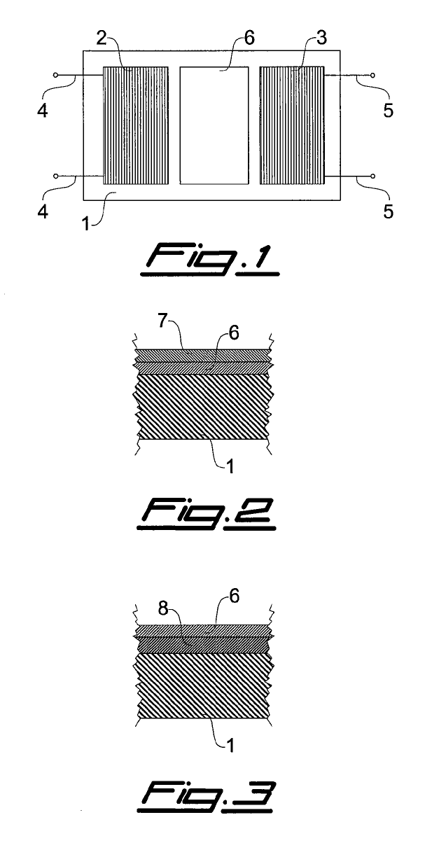

Referring to FIG. 1, it is seen that the gas sensor according to the application comprises, in a known way, a piezoelectric substrate 1 on which are arranged two inter-digital transducers 2, 3 provided with one or more input or output conductive lines 4, 5 for the wired or wireless connection to electric and/or electronic control devices. At least one layer 6 of a gas-sensitive material comprising a getter material is arranged on the surface of substrate 1 between transducers 2, 3, so that the molecules sorbed by this getter material can vary the frequency of an electric signal transmitted between transducers 2, 3. The vacuum level in an evacuated environment can thus be measured through a suitable calibration curve by arranging the sensor in this environment and by measuring the frequency variation.

In particular, the sensitive layer 6 is a getter film, which has a thickness between 0.5 and 5 μm (micrometers) and is applied onto substrate 1 by sputtering. The getter material can comprise metals such as zirconium, titanium, niobium, tantalum, vanadium, or alloys of these metals or of these and one or more other elements, chosen among chromium, manganese, iron, cobalt, nickel, aluminum, yttrium, lanthanum, and rare earths. Ti—V, Zr—V, Zr—Fe, Zr—Al and Zr—Ni binary alloys, and Zr—Mn—Fe, Zr—V—Fe and Zr—Co-MM ternary alloys (where MM represents mischmetal, a commercial mixture of yttrium, lanthanum and rare earths) proved to be particularly suitable, especially in the following compositions by weight: Zr 70%-V 24.6%-Fe 5.4% or Zr 84%-Al 16%.

Referring to FIG. 2, it is seen that, according to a first embodiment of the invention, a layer 7 of a material selectively permeable only to one or some determined gasses is arranged over sensitive layer 6, so that the sensor can measure concentrations of the gas permeating through the permeable layer 7, even in a non-evacuated environment. In particular, the permeable layer 7 has a thickness between 50 and 500 nm (nanometers) and comprises a noble metal, preferably palladium or platinum or an alloy thereof, so as to allow only hydrogen molecules to permeate, which are thus sorbed by the getter material of the sensitive layer 6.

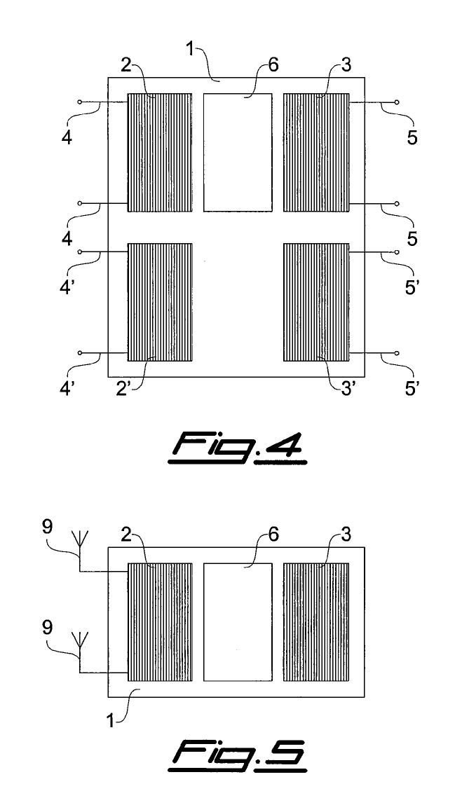

Referring to FIG. 3, it is seen that in a second embodiment of the invention a resistive device 8 suitable for being heated at an activation temperature for getter materials, in particular between 300 and 450° C., is arranged between substrate 1 and the sensitive layer 6. The resistive device 8 can be heated by a current flow, for example by powering the same through suitable electric feedthroughs (not shown in the Fig.), so as to carry out the first activation or the regeneration of the getter material of the sensitive layer 6. In fact, in the case of a hydrogen sensor, the heating of the sensitive layer 6 serves for releasing the hydrogen previously sorbed by the same.

Referring to FIG. 4, it is seen that in a third embodiment of the invention two pairs of inter-digital transducers 2, 2′, 3, 3′, each provided with one or more input or output lines 4, 4′, 5, 5′, are arranged side by side on the piezoelectric substrate 1. The sensitive layer 6 is arranged only between two inter-digital transducers 2, 3, so that differential measurements of the frequency variation of the electric signals transmitted between transducers 2, 2′ and 3, 3′ can be carried out.

Referring to FIG. 5, it is seen that in a fourth embodiment of the invention the first inter-digital transducer 2 is connected to one or more antennas 9 for receiving and/or transmitting radio signals from external devices. The second inter-digital transducer 3 is not connected to any device, neither by cable nor by radio, and simply reflects toward the first transducer 2 the signal received through the piezoelectric substrate 1 and modified by the sensitive layer 6 arranged between transducers 2, 3.

For manufacturing the sensors according to the present invention, a mask is mechanically aligned and then arranged in contact with a wafer of a piezoelectric substrate, on which a plurality of pairs of inter-digital transducers and, if required, a plurality of resistive devices are already applied. The mask is provided with calibrated openings having dimensions corresponding to those desired for the sensitive layers, which are then deposited onto the wafer by sputtering. For manufacturing hydrogen sensors, it is sufficient to apply permeable layers onto the sensitive layers deposited on the wafer, again by sputtering through a mask. After the deposition of the sensitive layers and, if any, of the permeable layers, the wafer is cut by mechanical or laser cutting for obtaining a plurality of sensors ready for use.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1.-17. (canceled)

18. A sensor comprising a piezoelectric substrate (1), a first pair of inter-digital transducers arranged on the substrate, at least one first layer (6) of a gas-sensitive material comprising a getter material arranged on the substrate between the pair of inter-digital transducers (2, 3), and a second layer (7) of a material permeable to at least one determined gas, the second layer being arranged over the first layer and also between the pair of inter-digital transducers, such that molecules sorbed by the getter material can vary a frequency of a signal transmitted between the pair transducers (2, 3).

19. The sensor according to claim 18, wherein the sensitive layer (6) is a getter film.

20. The sensor according to claim 19, wherein the getter material comprises a metal selected from the group consisting of zirconium, titanium, niobium, tantalum, vanadium, alloys of these metals, and alloys of these metals with at least one other element selected from the group consisting of chromium, manganese, iron, cobalt, nickel, aluminum, yttrium, lanthanum, and rare earths.

21. The sensor according to claim 20, wherein the getter material comprises an alloy selected from the group consisting of Ti—V, Zr—V, Zr—Fe, Zr—Al and Zr—Ni binary alloys, and Zr—Mn—Fe, Zr—V—Fe and Zr—Co-MM ternary alloys, where MM is a mixture of yttrium, lanthanum and rare earths.

22. The sensor according to claim 19, wherein the getter film has a thickness between 0.5 and 5 μm.

23. The sensor according to claim 18, wherein the permeable layer (7) comprises a noble metal or an alloy thereof.

24. The sensor according to claim 23, wherein the permeable layer (7) comprises palladium or platinum.

25. The sensor according to claim 18, wherein the permeable layer (7) has a thickness between 50 and 500 nm.

26. The sensor according to claim 18, further comprising a resistive device (8) suitable for being heated at an activation temperature for the getter material, the resistive device being arranged between the piezoelectric substrate (1) and the gas-sensitive layer (6).

27. The sensor according to claim 18, further comprising a second pair of inter-digital transducers (2′, 3′) arranged on the piezoelectric substrate (1), wherein the first layer (6) and second layer (7) are arranged only between the first pair of inter-digital transducers (2, 3).

28. The sensor according to claim 18, further comprising at least one antenna (9) for receiving and/or transmitting radio signals, the at least one antenna being connected to at least one of the pair of inter-digital transducer (2, 3).

29. The sensor according to claim 18, wherein the sensor is a vacuum sensor.

30. The sensor according to claim 18, wherein the sensor is a hydrogen sensor.

31. A process for manufacturing gas sensors, comprising the following operating steps:
applying a plurality of pairs of inter-digital transducers (2, 3; 2′, 3′) onto a wafer (1) of a piezoelectric substrate;
arranging on the wafer a first mask provided with a first set of calibrated openings, such that the first set of openings is located between a at least a first pair of the inter-digital transducers (2, 3);
depositing onto the wafer through the first mask a layer (6) of a gas-sensitive material comprising a getter material;
arranging on the wafer a second mask provided with a second set of calibrated openings, such that the second set of openings is located between the first pair of inter-digital transducers and over the layer of gas-sensitive material; and
depositing onto the wafer through the second mask a layer (7) of a material permeable to at least one determined gas.

32. The process according to claim 31, wherein the first and second masks are the same mask, such that only one mask is used and the steps of depositing the layer of a gas-sensitive material and of depositing the layer of a gas-permeable material are carried out using the same mask.

33. The process according to claim 31, wherein a resistive device is arranged on the wafer between at least the first pair of inter-digital transducers before depositing onto the wafer the layer of gas-sensitive material.

34. The process according to claim 31, wherein the steps of depositing are carried out by sputtering.
